(19) United States
(12) Patent Application Publication
(10) Pub. No.: US 2025/0208203 A1
(43) Pub. Date: Jun. 26, 2025

(54) INSPECTION METHOD, INSPECTION DEVICE, AND PROGRAM

(71) Applicant: Tokyo Electron Limited, Tokyo (JP)

(72) Inventors: Hiroaki HAYASHI, Yamanashi (JP); Satoshi SANO, Yamanashi (JP); Miyoshi TAKAHASHI, Yamanashi (JP); Kazuya AKIYAMA, Yamanashi (JP); Reo WADA, Yamanashi (JP)

(21) Appl. No.: 19/078,750

(22) Filed: Mar. 13, 2025

Related U.S. Application Data
(63) Continuation of application No. PCT/JP2023/033304, filed on Sep. 13, 2023.

(30) Foreign Application Priority Data
Sep. 27, 2022 (JP) 2022-153611

(51) Int. Cl. G01R 31/28

(52) U.S. Cl. CPC G01R 31/2891; G01R 31/2831

(57) ABSTRACT

An inspection method to be executed by an inspection device is provided. The inspection device includes: a mounting table on which an object of inspection is to be placed; and a probe card having a probe for use in inspecting the object. The inspection method includes: bringing the probe into contact with an electrode, formed in the object, based on a first offset value; setting a second offset value based on a needle mark that is formed when the probe is brought into contact with the electrode based on the first offset value; and bringing the probe into contact with the electrode based on the second offset value.

### CROSS-REFERENCE TO RELATED APPLICATION

This application is a continuation application of International Application No. PCT/JP2023/033304, filed on Sep. 13, 2023, and designated the U.S., which is based upon and claims the benefit of priority of prior Japanese Patent Application No. 2022-153611, filed on Sep. 27, 2022, the entire contents of which are incorporated herein by reference.

### BACKGROUND OF THE INVENTION

### 1. Field of the Invention

The present disclosure relates to an inspection method, an inspection device, and a program.

### 2. Description of the Related Art

In the process of manufacturing semiconductors, an inspection device (prober) is used to bring probes into contact with electrodes (pads) included in a wiring pattern formed on a semiconductor wafer, and inspect the electrical properties of the wiring pattern using a tester. During the probing, the positions where the probes contact the pads are corrected.

### SUMMARY OF THE INVENTION

One example of the present disclosure provides an inspection method to be executed by an inspection device including: a mounting table on which an object of inspection is to be placed; and a probe card having a probe for use in inspecting the object. The inspection method includes: bringing the probe into contact with an electrode, formed in the object, based on a first offset value; setting a second offset value based on a needle mark that is formed when the probe is brought into contact with the electrode based on the first offset value; and bringing the probe into contact with the electrode based on the second offset value.

### BRIEF DESCRIPTION OF THE DRAWINGS

FIG. 1 is a schematic cross-sectional view showing an example of an inspection device according to one embodiment of the present disclosure;

FIG. 2 is a diagram showing an example of a semiconductor wafer according to one embodiment of the present disclosure;

FIG. 3 is a block diagram showing an example hardware structure of a control device according to one embodiment of the present disclosure;

FIG. 4 is a block diagram showing an example functional structure of a control device according to one embodiment of the present disclosure;

FIG. 5 is a block diagram showing an example functional structure of an offset calculation unit according to one embodiment of the present disclosure;

FIG. 6A is a diagram showing a first example relationship between needle-mark data and offset values according to existing technology;

FIG. 6B is a diagram showing a second example relationship between needle-mark data and offset values according to existing technology;

FIG. 7 is a diagram showing an example relationship between needle-mark data and offset values according to one embodiment of the present disclosure;

FIG. 8 is a diagram showing a first example of calculating every offset value using multiple items of needle-mark data;

FIG. 9 is a diagram showing a second example of calculating every offset value using multiple items of needle-mark data;

FIG. 10 is a diagram showing a third example of calculating every offset value using multiple items of needle-mark data;

FIG. 11 is a diagram showing examples of needle-mark data according to one embodiment of the present disclosure;

FIG. 12 is a diagram showing example correction rules according to one embodiment of the present disclosure;

FIG. 13 is a diagram showing example offset values upon application of correction rules to needle-mark data;

FIG. 14 is a conceptual diagram showing an example of offset information according to one embodiment of the present disclosure;

FIG. 15 is a flowchart showing an example of an inspection method according to one embodiment of the present disclosure; and

FIG. 16 is a flowchart showing an example of an offset calculation process according to one embodiment of the present disclosure.

### DETAILED DESCRIPTION OF THE PREFERRED EMBODIMENTS

For example, unexamined Japanese patent application No. 2006-278381 discloses a prober. According to unexamined Japanese patent application No. 2006-278381, a post-contact image, which captures an image of pads after probes have come into contact with the pads, and a pre-contact image, capturing the pads prior to the probes' contact with the pads, are compared, so as to obtain the positions of the latest needle-mark ranges, left when the probes contacted the electrodes, among multiple needle-mark ranges shown in the post-contact image, and determine how much the positions the probes contacted deviate with respect to the pads, based on the positions of the latest needle-mark ranges.

The present disclosure therefore aims to provide a technique that allows probes to accurately contact electrodes formed on an inspection object.

According to at least one aspect of the present disclosure, thus, probes can be brought into accurate contact with electrodes formed on an inspection object.

Hereinafter, an embodiment for carrying out the present disclosure will be described with reference to the accompanying drawings. Throughout the drawings, the same components are assigned the same reference numerals, so that duplicated explanation may be omitted.

### EMBODIMENT

### Summary

The size of electrodes (pads) formed on an inspection object (hereinafter simply “object”) has been decreasing; accordingly, inspection devices are required to enable contact with higher accuracy. The deviation in position occurring where a probe contacts a pad (“contact position”) is caused by a combination of a number of factors, including the mechanical precision and inherent variability of the inspection device, the mechanical precision and inherent variability of the probe card, temperature changes of the mounting table, and the heat produced by the semiconductor wafer, making it difficult to improve the accuracy of contact. It is therefore important to maintain a constant level of accuracy of contact regardless of what combination of inspection device, probe card, and semiconductor wafer temperature applies.

With existing inspection devices, the positions of needle-mark ranges, formed when the probes contact pads, are checked on a regular basis, and the offset values for correcting the contact positions are adjusted. However, with existing inspection devices, this adjustment of offset values needs to be done manually by the user, and this is a factor that leads to reduced work performance and productivity.

One embodiment of the present disclosure therefore provides an inspection device that enables automatic adjustment of offset values based on contact positions where probes contact pads. The inspection device of the present embodiment implements software including an algorithm and data sets for adjusting the positions where probes contact pads, based on needle-mark data indicating the probes' actual contact positions, rules for adjusting the offset values, predetermined setting values, and offset values used in the past.

### <Structure of Inspection Device>

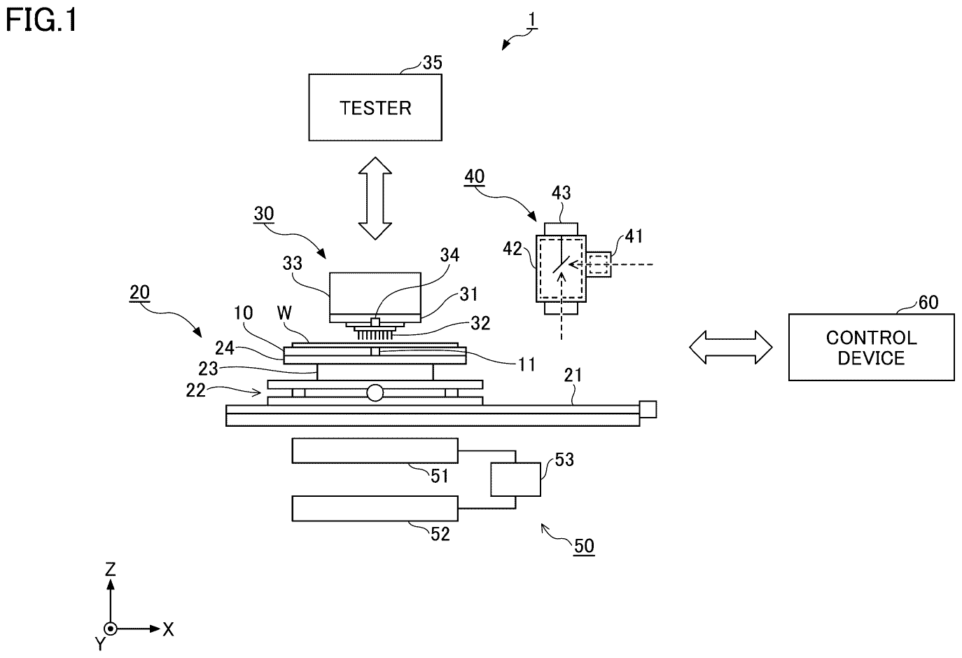

FIG. 1 is a schematic cross-sectional view showing an example of an inspection device according to the present embodiment. As shown in FIG. 1, the inspection device 1 has a mounting table 10, a mounting table driving unit 20, an inspection unit 30, an image-capturing unit 40, a temperature control device 50, and a control device 60.

The mounting table 10 holds a semiconductor wafer W by suction, by using a vacuum chuck, an electrostatic chuck, or the like. The semiconductor wafer W is an example of an inspection object. The mounting table driving unit 20 moves the mounting table 10 relative to the inspection unit 30 or the image-capturing unit 40. The image-capturing unit 40 captures an image of the semiconductor wafer W and acquires a gradational image of the semiconductor wafer W. The temperature control device 50 controls the temperature of the semiconductor wafer W placed on the mounting table 10. The control device 60 controls other components of the inspection device 1.

The mounting table driving unit 20 has an X-direction moving mechanism 21, a Y-direction moving mechanism 22, a Z-direction moving mechanism 23, and a rotation mechanism 24. The X-direction moving mechanism 21 moves the mounting table 10 in the X direction shown in FIG. 1. The Y-direction moving mechanism 22 moves the mounting table 10 in the Y direction shown in FIG. 1. The Z-direction moving mechanism 23 moves the mounting table 10 in the Z direction shown in FIG. 1. The rotation mechanism 24 rotates the mounting table 10 about a rotating axis that is perpendicular to the XY plane.

The inspection unit 30 has a probe card 31, probes 32, a test head 33, and an infrared sensor 34. The probe card 31 is positioned above the mounting table 10 to face the mounting table 10. The probe card 31 has multiple probes 32, which are contacts aligned two-dimensionally. The probe card 31 is connected with the test head 33. An external tester 35 is connected to the test head 33.

When a probe 32 contacts a pad of an electronic device formed on the semiconductor wafer W, the probe 32 supplies an electrical signal, which is output from the tester 35, to the electronic device via the test head 33. Also, the probe 32 transmits an electrical signal, output from the electronic device, to the tester 35 via the test head 33. In this way, the probe 32 and the test head 33 function as a supply member that supplies power to the electronic device.

The probe card 31 has a base substrate and a multi-layer ceramic substrate. Multiple probes 32 protrude from the multi-layer ceramic substrate. The infrared sensor 34 is attached to the multi-layer ceramic substrate to measure the temperature of the electronic device during inspection.

The infrared sensor 34 is, for example, a non-contact temperature sensor that detects the temperature of an object being subject to measurement, from the amount of infrared radiation emitted in accordance with the object's temperature. The infrared sensor 34 can be implemented using various existing elements, such as a thermal diode. The infrared sensor 34 may also be provided in the form of an infrared camera or a radiation thermometer.

The surface of the mounting table 10, on which the semiconductor wafer W is placed, has suction holes for holding the semiconductor wafer W by suction. Also, the semiconductor-wafer-mounting surface has multiple temperature sensors 11, embedded in positions spaced apart from each other in plan view. These temperature sensors 11 can be thermocouples, for example.

The image-capturing unit 40 has a lighting unit 41, an optical system 42, and an image-capturing device 43. The lighting unit 41 emits illuminating light. The lighting unit 41 is implemented, for example, using a halogen lamp. The optical system 42 guides the illuminating light to the semiconductor wafer W. Furthermore, the reflected light from the semiconductor wafer W is incident on the optical system 42. The image-capturing device 43 converts, for example, an image of the semiconductor wafer W formed by the optical system 42 into an electrical signal, and outputs image data of the semiconductor wafer W. The image-capturing device 43 is implemented, for example, using an array of charge-coupled device (CCD) elements.

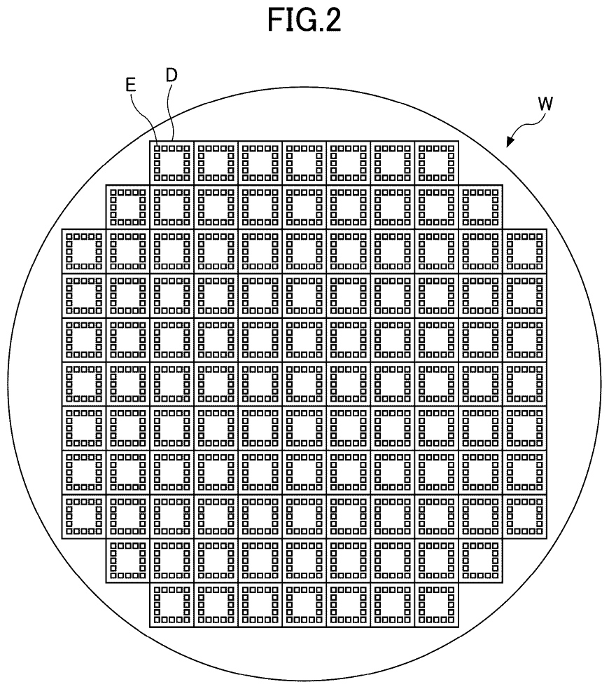

FIG. 2 is a diagram showing an example of a semiconductor wafer W. As shown in FIG. 2, the semiconductor wafer W is a substrate that is subject to inspection. By performing etching and interconnect processes on this substantially disk-shaped silicon substrate, multiple electronic devices D are formed, at predetermined intervals, on the surface of the semiconductor wafer W. Pads E are formed on the surface of each electronic device D and electrically connected to circuit elements inside the electronic device D. By applying a voltage to the pads E, a current can travel through the circuit elements inside each electronic device D.

Referring back to FIG. 1, the temperature control device 50 has a heating mechanism 51, a cooling mechanism 52, and a temperature controller 53. The temperature control device 50 controls the heating by the heating mechanism 51, the cooling by the cooling mechanism 52, and the adjustment of heating and cooling by the temperature controller 53, thus allowing each electronic device D formed on the semiconductor wafer W on the mounting table 10 to have a constant target temperature.

The heating mechanism 51 is structured as a light-emitting mechanism. The heating mechanism 51 emits light onto the semiconductor-wafer-mounting surface of the mounting table 10 to heat up the mounting table 10, thereby heating the semiconductor wafer W as well as the electronic devices D formed on the semiconductor wafer W.

The heating mechanism 51 has, for example, multiple LEDs that emit light to the semiconductor wafer W and functions as a source of heat. The LEDS emit, for example, near-infrared light. The light emitted from the LEDs passes through the mounting table 10 made of a light-transmitting material and is incident on the semiconductor-wafer-mounting surface. If the light from the LEDs is near-infrared light, polycarbonate, quartz, polyvinyl chloride, acrylic resin, or glass can be used as the light-transmitting material.

The cooling mechanism 52 has a chiller unit that stores a refrigerant and refrigerant piping for circulating the refrigerant. For the refrigerant, for example, water, which is a liquid transparent to the light emitted from the heating mechanism 51, is used. The refrigerant piping is connected to a supply port and a discharge port of a refrigerant flow path formed inside the mounting table 10, and to the chiller unit. The refrigerant in the chiller unit is circulated and supplied to the refrigerant flow path, via the refrigerant piping, by means of a pump provided in the refrigerant piping.

When an electronic device D is inspected, the temperature controller 53 receives a measurement signal that indicates the temperature of the electronic device D measured by the infrared sensor 34. The temperature controller 53 controls the heating mechanism 51 and cooling mechanism 52 based on the measurement signal, and executes feedback control of the temperature of the electronic device D. In this way, the temperature controller 53 executes accurate temperature control. In addition, when no inspection is in progress, the temperature controller 53 executes temperature control by receiving temperature measurement signals from the temperature sensors 11 provided on the semiconductor-wafer-mounting surface of the mounting table 10.

### <Hardware Structure of Control Device>

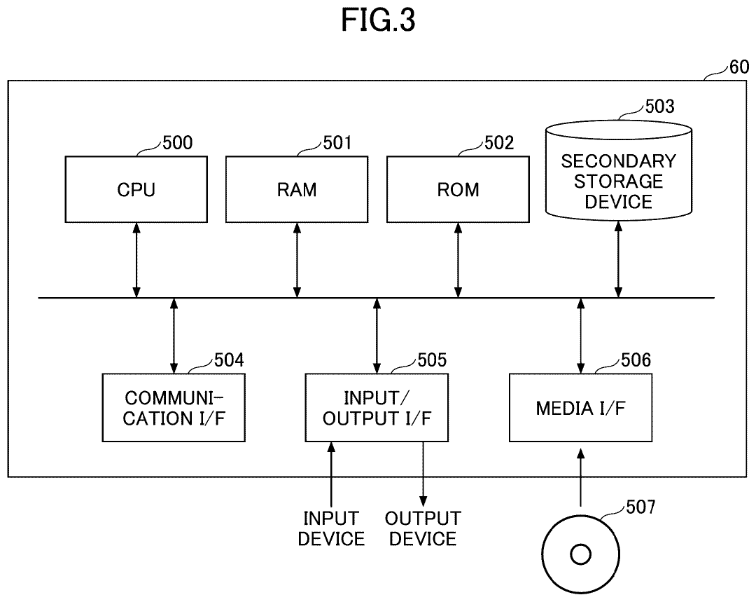

FIG. 3 is a block diagram showing an example hardware structure of the control device 60 of the present embodiment. As shown in FIG. 3, the control device 60 includes a central processing unit (CPU) 500, a random access memory (RAM) 501, a read-only memory (ROM) 502, a secondary memory device 503, a communication interface (I/F) 504, an input/output I/F 505, and a media I/F 506.

The CPU 500 operates based on programs stored in the ROM 502 or the secondary memory device 503, and controls each component. The ROM 502 stores the boot program that is executed by the CPU 500 when the control device 60 is started, programs that rely on the hardware of the control device 60, and so forth.

The secondary memory device 503 is, for example, a hard disk drive (HDD) or a solid state drive (SSD). The secondary memory device 503 stores the programs executed by the CPU 500 and the data to be used when the programs are run. The CPU 500 reads the programs from the secondary memory device 503, loads them onto the RAM 501, and executes the loaded programs.

The communication I/F 504 communicates with other components of the inspection device 1 via a communication link such as a local area network (LAN). The communication I/F 504 receives data from other components of the inspection device 1 via the communication link and sends the data to the CPU 500. Data that is generated by the CPU 500 is transmitted to other components of the inspection device 1 via the communication link.

The CPU 500 controls input devices such as a keyboard and output devices such as a display, via the input/output I/F 505. When a signal is input from an input device, the CPU 500 acquires this signal via the input/output I/F 505 and sends it to the CPU 500. The CPU 500 also outputs the generated data to an output device via the input/output I/F 505.

The media I/F 506 reads the programs or data stored in the recording medium 507 and stores them in the secondary memory device 503. The recording medium 507 is, for example, an optical recording medium such as a digital versatile disc (DVD) or a phase change rewritable disc (PD), a magneto-optical recording medium such as a magneto-optical disk (MO), a tape medium, a magnetic recording medium, or a semiconductor memory.

The CPU 500 of the control device 60 reads the programs loaded onto the RAM 501 from the recording medium 507 and stores them in the secondary memory device 503. In a different example, programs may be obtained from other devices via a communication link and stored in the secondary memory device 503.

### <Functional Structure>

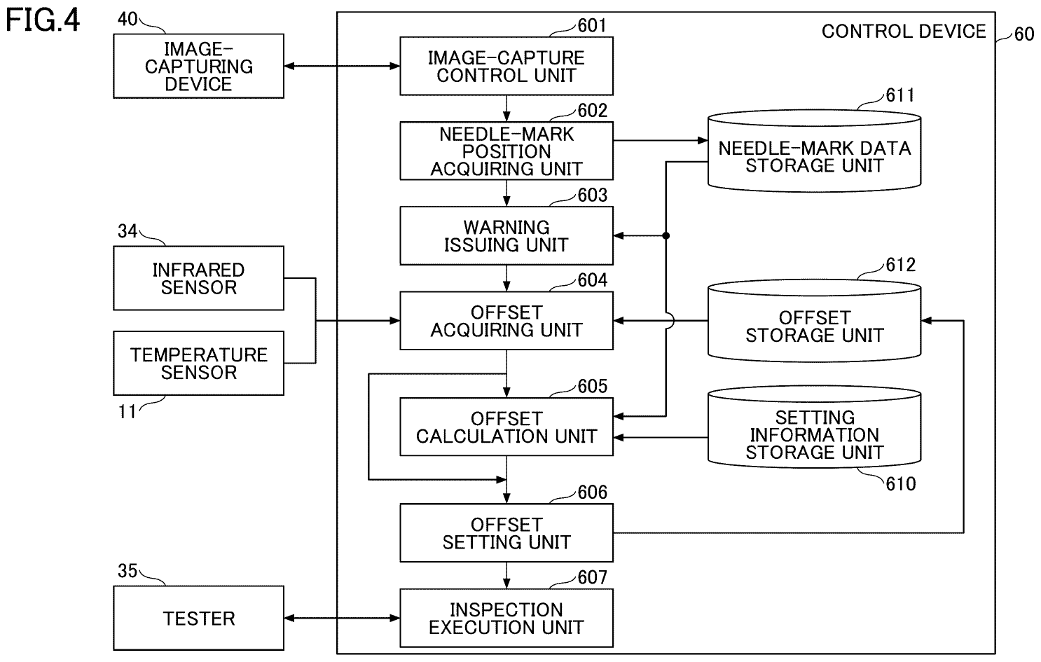

The functional structure of the control device according to the present embodiment will be described with reference to FIG. 4. FIG. 4 is a block diagram showing an example functional structure of the control device 60 of the present embodiment.

As shown in FIG. 4, the control device 60 according to the present embodiment includes an image-capture control unit 601, a needle-mark position acquiring unit 602, a warning issuing unit 603, an offset acquiring unit 604, an offset calculation unit 605, an offset setting unit 606, an inspection execution unit 607, a setting information storage unit 610, a needle-mark data storage unit 611, and an offset storage unit 612.

The image-capture control unit 601, the needle-mark position acquiring unit 602, the warning issuing unit 603, the offset acquiring unit 604, the offset calculation unit 605, the offset setting unit 606, and the inspection execution unit 607 are implemented, for example, as the CPU 500 shown in FIG. 3 executes programs loaded on the RAM 501. The setting information storage unit 610, the needle-mark data storage unit 611, and the offset storage unit 612 are implemented by, for example, the RAM 501 or the secondary memory device 503 shown in FIG. 3.

The setting information storage unit 610 stores, in advance, the setting information that is used to calculate offset values. The setting information includes predetermined rules and predetermined setting values. The predetermined rules include calculation rules for controlling the timing of calculating offset values, and correction rules for correcting the calculated offset values. The setting information can be edited at any time through user operations. The setting information will be described in greater detail later.

The needle-mark data storage unit 611 stores needle-mark data that is acquired by the needle-mark position acquiring unit 602. “Needle-mark data” as used herein refers to data that indicates the position of a needle-mark range that is formed when a probe 32 contacts a pad E (also referred to as “contact position”).

The offset storage unit 612 stores offset information related to the offset values set by the offset setting unit 606. The offset information includes, for example, an offset value that is set, and environment information that represents the environment as of when the offset value was calculated. The offset information will be described in greater detail later.

The image-capture control unit 601 controls the image-capturing unit 40 to capture an image of the semiconductor wafer W such that the pads E that the probes 32 have contacted are included in the image. The image-capturing unit 40 captures an image of the semiconductor wafer W placed on the mounting table 10 under the control of the image-capturing control unit 601. The image captured by the image-capturing unit 40 (hereinafter also referred to as a “post-contact image”) is gradational and acquired by the image-capturing control unit 601.

The needle-mark position acquiring unit 602 acquires the positions of the latest needle-mark ranges from the post-contact image acquired by the image-capture control unit 601. The needle-mark position acquiring unit 602 stores needle-mark data that indicates the positions of the latest needle-mark ranges acquired, in the needle-mark data storage unit 611.

The warning issuing unit 603 decides whether or not to bring the probes 32 into contact with the pads E (in other words, whether or not to continue the inspection) based on the positions of the latest needle-mark ranges acquired by the needle-mark position acquiring unit 602. The warning issuing unit 603 decides whether or not to bring the probes 32 into contact with the pads E based on correction rules provided in the setting information. If the warning issuing unit 603 decides not to bring the probes 32 into contact with the pads E, the warning issuing unit 603 issues a warning to the user and stops the inspection.

For example, if the cumulative value of deviations between the positions of needle-mark ranges and the center position of the corresponding pad E exceeds a predetermined first threshold, the warning issuing unit 603 may decide not to bring the probes 32 into contact with the pads E and output a warning. The warning issuing unit 603 may also decide not to bring the probes 32 into contact with the pads E and output a warning if the deviations between the positions of the latest needle-mark ranges and the center position of the corresponding pad E exceed a predetermined second threshold. The first threshold or the second threshold that the warning issuing unit 603 uses when making the above decisions may be provided in the setting information.

The offset acquiring unit 604 acquires offset information, which includes environment information that matches the current environment, from the offset information stored in the offset storage unit 612. When the offset acquiring unit 604 acquires offset information that matches the current environment, the offset acquiring unit 604 sends it to the offset setting unit 606.

The offset calculation unit 605 calculates new offset values based on the needle-mark data stored in the needle-mark data storage unit 611. The offset calculation unit 605 calculates new offset values according to the setting information stored in the setting information storage unit 610.

The offset setting unit 606 sets the offset values calculated by the offset calculation unit 605 as current offset values. The offset setting unit 606 receives offset information from the offset acquiring unit 604, and sets the offset values included in the offset information as current offset values.

The inspection execution unit 607 controls the mounting table driving unit 20 and the tester 35 to perform an electrical inspection of the semiconductor wafer W placed on the mounting table 10. The inspection execution unit 607 controls the mounting table driving unit 20 based on the current offset values set by the offset setting unit 606, to bring the probes 32 into contact with the pads E formed on the semiconductor wafer W placed on the mounting table 10. The tester 35 inspects the electrical properties of the electronic device D by supplying power to the probes 32 via the test head 33.

### <<Offset Calculation Unit>>

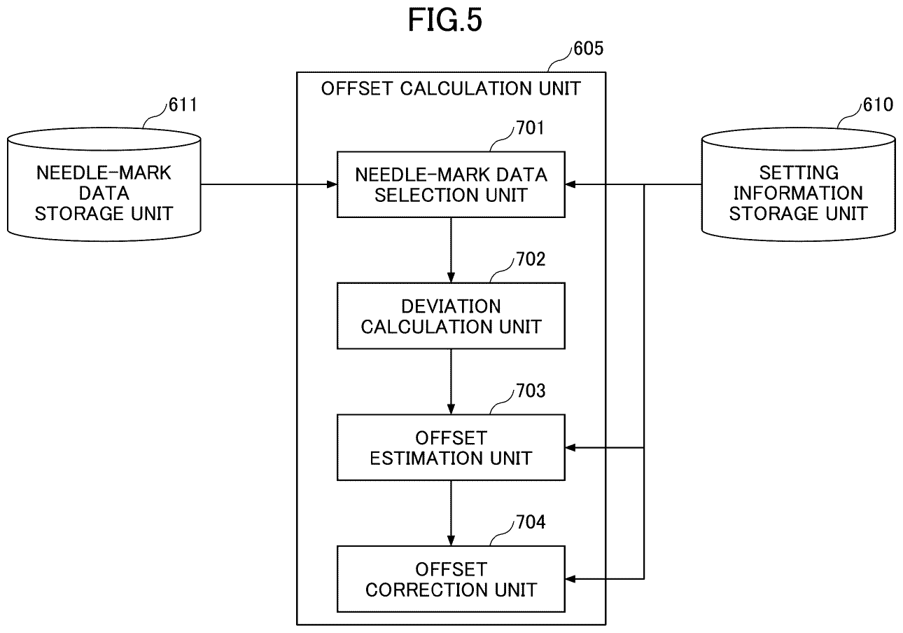

FIG. 5 is a block diagram showing an example functional structure of the offset calculation unit 605 according to the present embodiment. As shown in FIG. 5, the offset calculation unit 605 according to the present embodiment includes a needle-mark data selection unit 701, a deviation calculation unit 702, an offset estimation unit 703, and an offset correction unit 704.

The needle-mark data selection unit 701 selects the needle-mark data to be used to calculate the offset values, from among the needle-mark data stored in the needle-mark data storage unit 611. The needle-mark data selection unit 701 selects the needle-mark data based on calculation rules and setting values provided in the setting information.

For every piece of needle-mark data selected by the needle-mark data selection unit 701, the deviation calculation unit 702 calculates the deviation between the position of the needle-mark range and the center position of the pad E. A “deviation” as used herein refers to the distance between the position of a needle-mark range and the center position of a corresponding pad E, and is a vector that indicates the direction from the center position of the pad E to the position of the needle-mark range.

The offset estimation unit 703 estimates the offset values based on the deviations calculated by the deviation calculation unit 702. The offset estimation unit 703 estimates the offset values according to the offset calculation method provided in the setting information.

The offset correction unit 704 corrects the offset values estimated by the offset estimation unit 703. The offset correction unit 704 corrects the offset values based on correction rules provided in the setting information.

### <<Setting Information>>

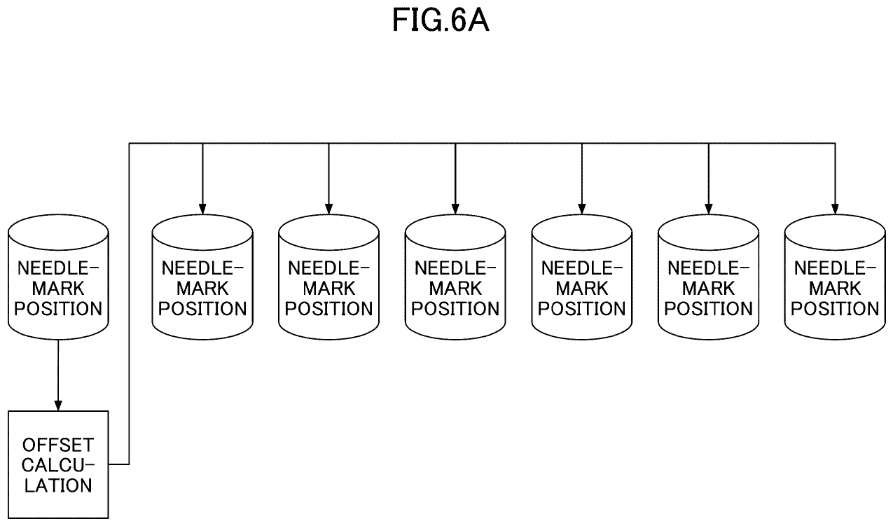

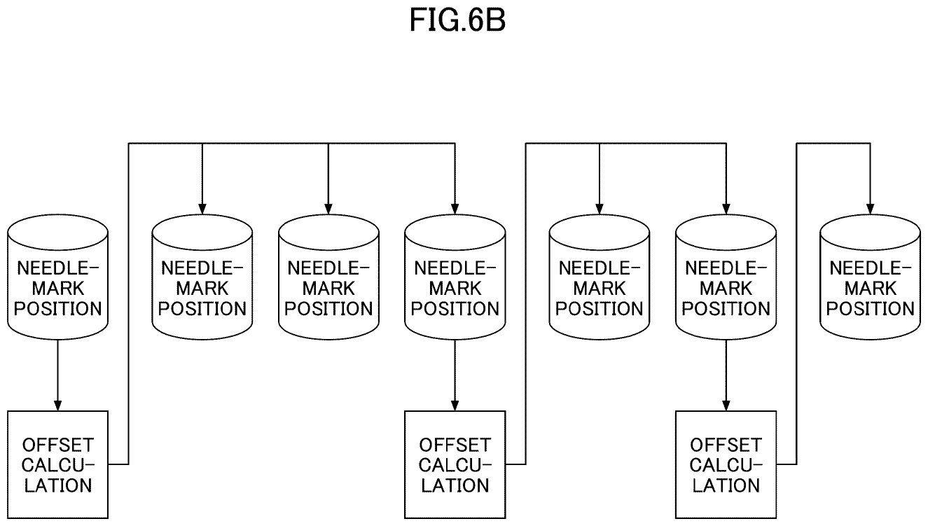

The setting information according to the present embodiment will be described with reference to FIG. 6A to FIG. 13.

### (Calculation Rules)

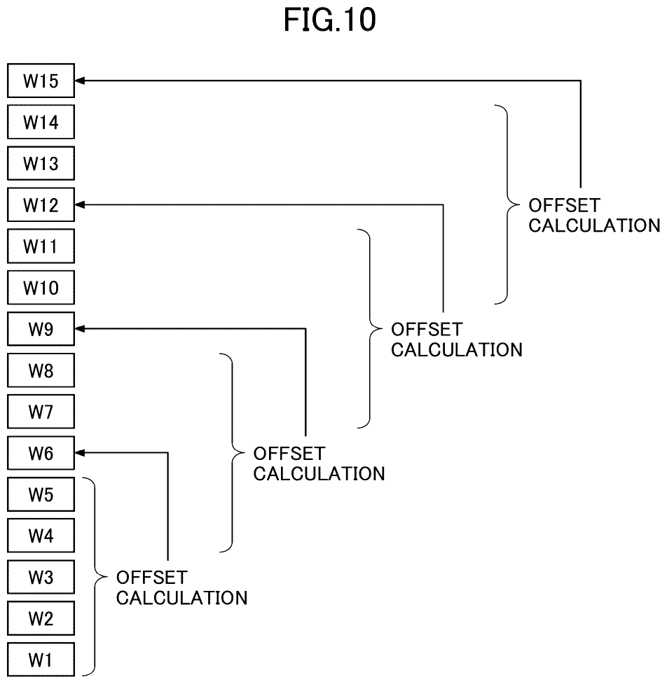

FIG. 6A, FIG. 6B, and FIG. 10 are diagrams for explaining examples of calculation rules according to the present embodiment. “Calculation rules” as used herein refers to rules for controlling the timing for calculating offset values.

FIG. 6A is a diagram showing a first example relationship between needle-mark data and offset values according to existing technology. FIG. 6B is a diagram showing a second example relationship between needle-mark data and offset values according to existing technology. In existing technology, for example, as shown in FIG. 6A, an offset value is first calculated and set based on needle-mark data, and the same offset value is used continuously in subsequent inspections. Alternatively, referring now to FIG. 6B, once an offset value is calculated and set based on needle-mark data, this offset value is used multiple times in a row, and then adjusted at a given timing.

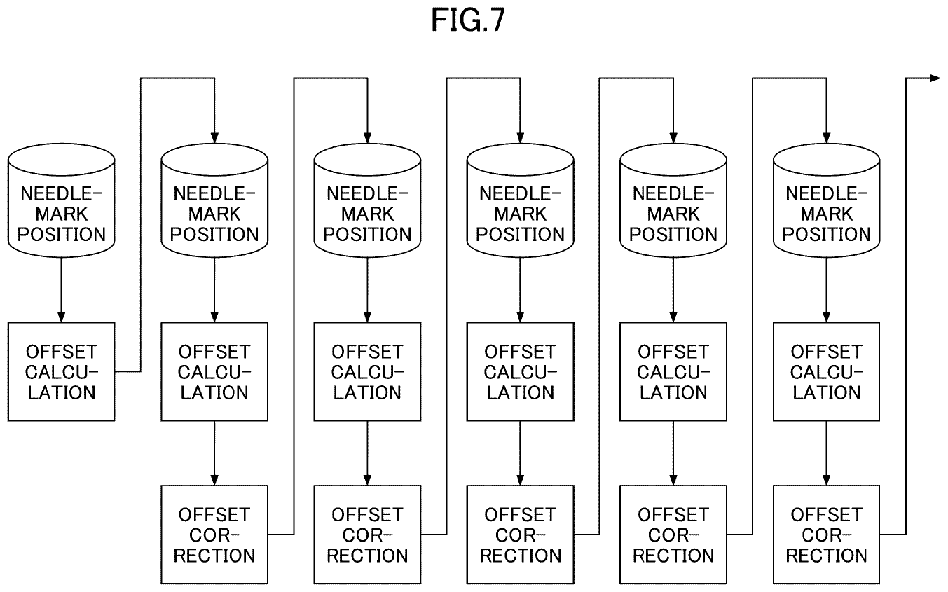

FIG. 7 is a diagram showing an example relationship between needle-mark data and offset values according to the present embodiment. As shown in FIG. 7, according to the present embodiment, an offset value is first calculated based on needle-mark data. When this offset value is set, an inspection is performed once based on this offset value, and needle-mark data is acquired again. Next, based on the needle-mark data acquired thus, a new offset value is calculated and corrected according to a predetermined correction rule. Subsequently, an inspection is performed once based on the corrected offset value, and needle-mark data is acquired once again.

The inspection device 1 of the present embodiment thus enables automatic adjustment of offset values by repeating acquiring needle-mark data, calculating an offset value, and correcting the offset value. As a result of this, the inspection device 1 of the present embodiment achieves improved work performance and productivity.

Note that, although FIG. 7 shows an example in which an offset value is calculated and corrected every time one item of needle-mark data is acquired, it is also possible to calculate and correct an offset value when a predetermined number of items of needle-mark data are acquired. The timing for calculating and correcting offset values may be provided in the setting information.

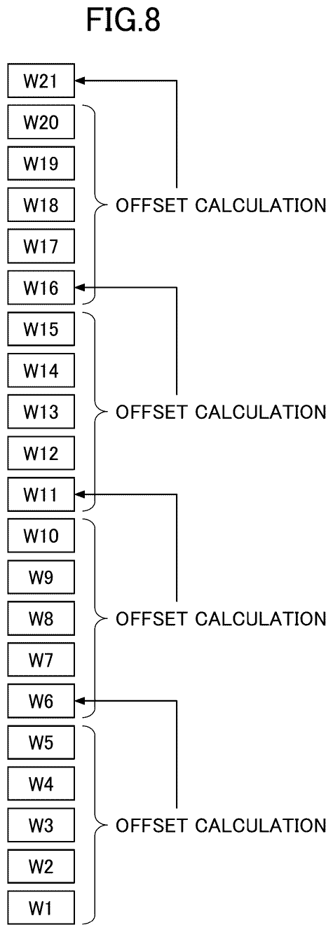

When an offset value is calculated using multiple items of needle-mark data, the method of selecting the needle-mark data to be used to calculate the offset value may be defined. FIG. 8 shows a first example of calculating every offset value using multiple items of needle-mark data. Referring to the example shown in FIG. 8, first, the first to fifth semiconductor wafers W1 to W5 are inspected, and a new offset value is calculated based on semiconductor wafers W1 to W5 after the inspection. Next, the sixth to tenth semiconductor wafers W6 to W10 are inspected based on the new offset value, and a new offset value is calculated again based on semiconductor wafers W6 to W10 after the inspection. In this way, it is possible to calculate an offset value based on the five most recently inspected semiconductor wafers W.

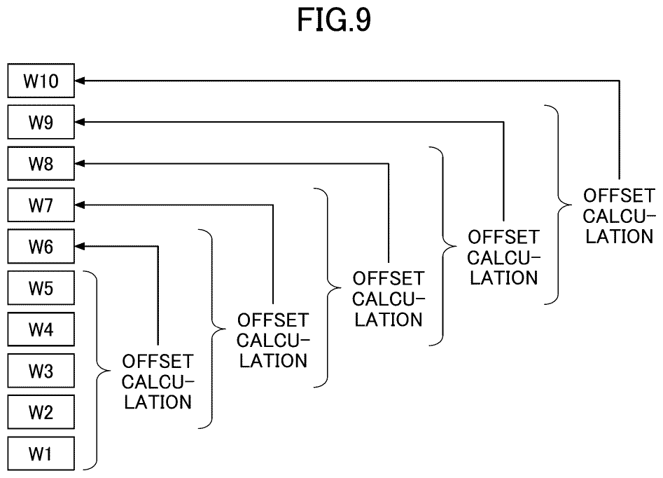

FIG. 9 shows a second example of calculating every offset value using multiple items of needle-mark data. Referring to the example shown in FIG. 9, a new offset value is first calculated based on semiconductor wafers W1 to W5 that have been inspected. Then, the sixth semiconductor wafer W6 is inspected based on the new offset value, and a new offset value is calculated again based on semiconductor wafers W2 to W6 after the inspection. In this way, again, it is possible to calculate an offset value based on one most recently inspected semiconductor wafer W and four semiconductor wafers W inspected before that.

FIG. 10 shows a third example of calculating every offset value using multiple items of needle-mark data. Referring to the example shown in FIG. 10, a new offset value is first calculated based on semiconductor wafers W1 to W5 that have been inspected. Then, the sixth to eighth semiconductor wafers W6 to W8 are inspected based on the new offset value, and a new offset value is calculated again based on semiconductor wafers W4 to W8 after the inspection. In this way, it is also possible to calculate an offset value based on the three most recently inspected semiconductor wafers W and two semiconductor wafers W inspected before that.

Note that the number of items of needle-mark data to be used to calculate an offset value and the number of most recently acquired needle-mark data items among them may be provided in the setting information. For example, in the first example shown in FIG. 8, the number of items of needle-mark data may be set to 5, and the number of the most recent needle-mark data items may be set to 5. Similarly, in the second example shown in FIG. 9, the number of items of needle-mark data may be set to 5, and the number of the most recent needle-mark data items may be set to 1. In the third example shown in FIG. 10, the number of items of needle-mark data may be set to 5, and the number of the most recent needle-mark data items may be set to 3.

### (Correction Rules)

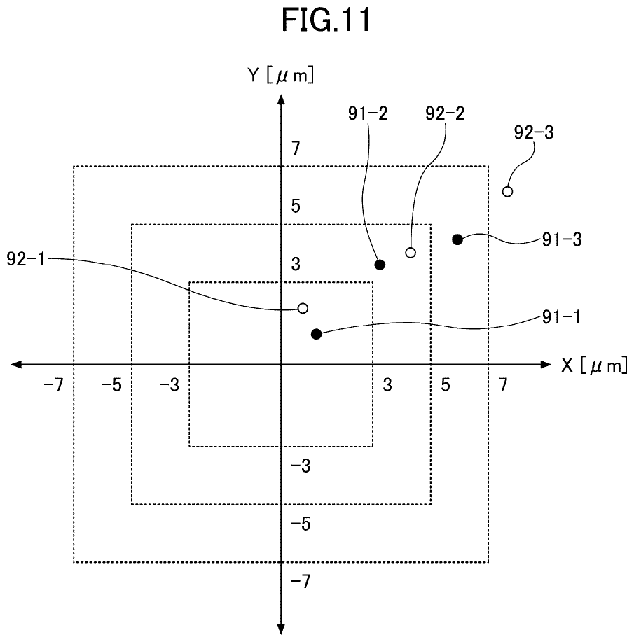

FIG. 11 to FIG. 13 are diagrams for explaining examples of correction rules according to the present embodiment. “Correction rules” as used herein refers to rules for correcting offset values calculated based on needle-mark data.

FIG. 11 is a diagram showing examples of needle-mark data according to the present embodiment. As shown in FIG. 11, the positions of needle-mark ranges can be represented on an XY plane with the center position of a pad E being the origin. Referring to the example shown in FIG. 11, the needle-mark range positions 91-1 to 91-3 (hereinafter also referred to as “original positions”) are used to calculate current offset values, and shown as closed circles. Also, the needle-mark range positions 92-1 to 92-3 (hereinafter also referred to as “new positions”) are marked when the probes 32 are brought into contact with pads E based on the current offset values, and shown as open circles.

Note that, in the present embodiment, multiple items of needle-mark data are used to calculate an offset value. Therefore, FIG. 11 shows the original position and a new position of each item of needle-mark data on the same XY plane.

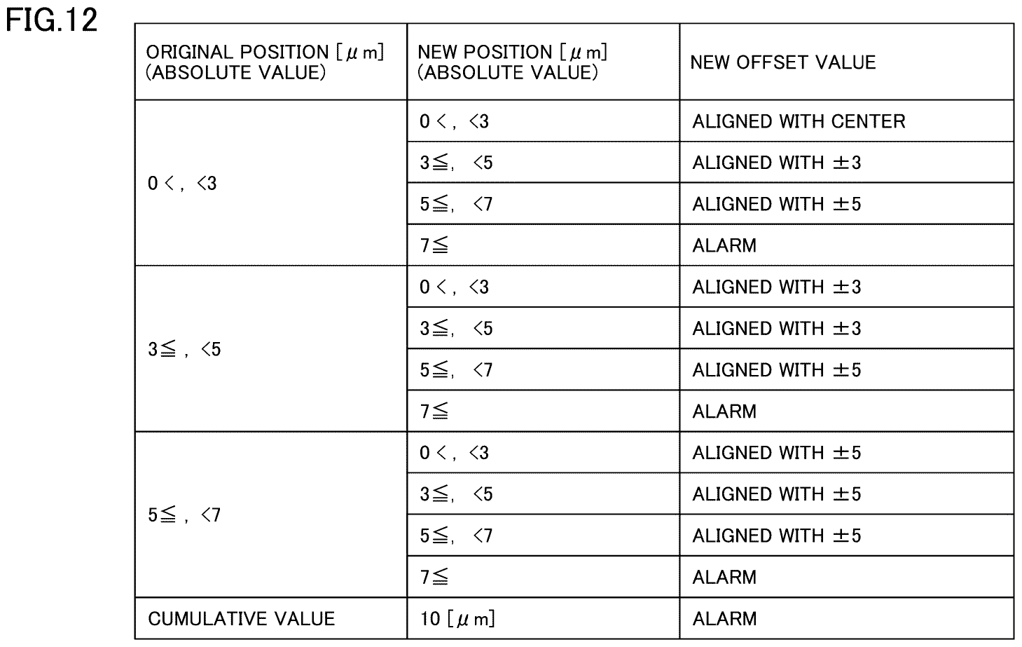

FIG. 12 is a diagram showing example correction rules according to the present embodiment. Referring to FIG. 12, the correction rules according to the present embodiment are designed such that new offset values are calculated for all combinations of: the ranges in which the original positions 91-1 to 91-3 exist; and the ranges in which the new positions 92-1 to 92-3 exist.

Note that, in the example shown in FIG. 11, the original positions 91-1 to 91-3 and the new positions 92-1 to 92-3 are all in the same quadrant (in other words, the contact positions tend to shift in a certain direction), so that these original positions and new positions are shown in their absolute values in the correction rules of FIG. 12. If the original positions and new positions are in different quadrants (that is, if the contact positions shift randomly), the correction rules may be defined based on combinations of ranges including signs.

For example, if an original position is in a range less than +3 μm from the origin (that is, the center position of the corresponding pad E) and its new position is in a range located less than +3 μm from the origin, an offset is calculated and used as is as a new offset value without correction. Note that the offset value calculated is an offset value with respect to the center position of the pad E as the target position. Here, the target position is the position on the pad E with which the contact position is to be aligned.

Also, for example, if an original position is in a range less than +3 μm from the origin and its new position is in a range 3 μm or more but less than ±5 μm from the origin, an offset value is calculated and corrected to an offset value for aligning the contact positions with a ±3-μm position. The “±3 μm position” may be any of the coordinates (+3, +3), (+3, −3), (−3, +3), and (−3, −3) on the XY plane, where the center position of the corresponding pad E is the origin.

With which coordinates the contact position is aligned depends on which quadrant the original position and new position are in. For example, in the example shown in FIG. 11, the original positions and new positions are all in the first quadrant, so that the offset values are corrected to offset values for aligning the contact positions with the coordinates (+3, +3). Alternatively, if the original positions and new positions were in the third quadrant, the offset values would be corrected to offset values for aligning the contact positions with the coordinates (−3, −3).

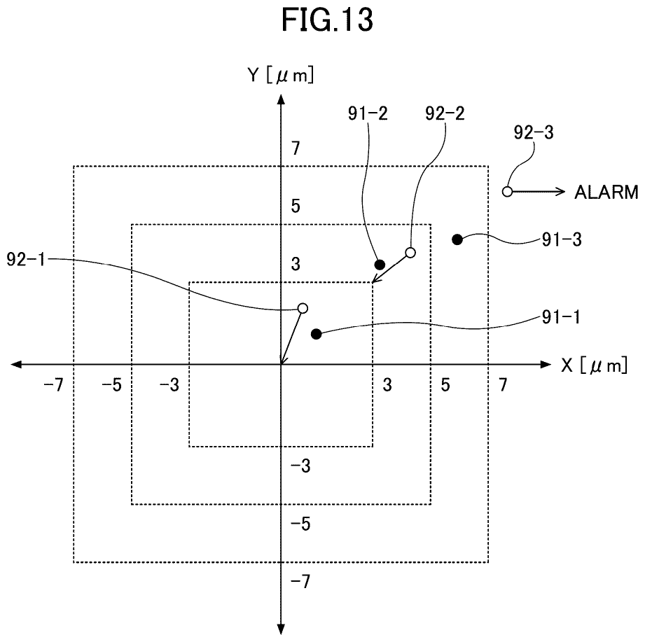

FIG. 13 is a diagram showing examples of offset values used when the correction rules of FIG. 12 are applied to the needle-mark data of FIG. 11. Referring to FIG. 13, the offset value calculated based on the new position 92-1 is used as is as an offset value for aligning the contact position with the center position of the pad E. This is because the new position 92-1 is in a range that is less than +3 μm from the origin and the original position 91-1 corresponding to the new position 92-1 is in a range that is less than +3 μm from the origin.

Also, the offset value that is calculated based on the new position 92-2 is corrected to an offset value for aligning the contact position with the coordinates (+3, +3). This is because the new position 92-2 is in a range that is +3 μm or more and less than +5 μm from the origin and the original position 91-2 corresponding to the new position 92-2 is in a range that is +3 μm or more and less than +5 μm from the origin.

As for the new position 92-3, the offset value is not corrected, and an alarm is issued instead. This is because the new position 92-3 is in a range that is ±7 μm or beyond from the origin. In this case, the inspection device 1 stops the inspection, and does not bring the probe 32 in contact with the pad E based on an offset value calculated based on the new position 92-3.

The correction rules may provide for issuing an alarm based on the cumulative value of deviations. The examples of correction rules shown in FIG. 12 provide for issuing an alarm when the cumulative value of deviations becomes 10 μm or more. In this case, again, the inspection device 1 stops the inspection, and does not bring the probe 32 into contact with the pad E based on a newly calculated offset value.

Note that the cumulative value of deviations is calculated including the signs. For example, if the first deviation is +5 and the second deviation is −2, the cumulative value of deviations is |3|. “|·|” is the expression to represent the absolute value of the value “·”.

If a contact position shows a significant deviation, an event other than one in which the contact position's variability is caused by the temperature of the probe card 31 or the semiconductor wafer W may be taking place (for example, the inspection device may be malfunctioning). Also, if a contact position is deviated beyond the corresponding pad E, the probe 32 may contact a position outside the pad E. Therefore, if a contact position shows a significant deviation, the inspection is stopped and an alarm is issued. The user inspects the inspection device 1 in response to the alarm, and takes action such as repairing or replacing the inspection device 1 if needed. This makes it possible to prevent problems from occurring.

### (Setting Values)

The setting information according to the present embodiment includes setting values that define the reference value and other values to be used when implementing various rules. The setting values according to the present embodiment include outliers, values to indicate whether or not to use outliers, values to indicate whether or not to use initial values, the data period, the method of calculating offset, and so forth.

An “outlier” as used herein refers to a setting value that defines the reference value to be used when determining whether or not needle-mark data is an outlier. An outlier is a value that is markedly different from other needle-mark data.

Whether or not to use an outlier is determined by setting values that indicate whether or not the needle-mark data corresponding to the outlier is used to calculate an offset value. Using an outlier when calculating an offset value might make it difficult to calculate a reliable offset value. Consequently, whether or not needle-mark data that indicates an outlier is used to calculate an offset value is made configurable.

Whether or not to use initial values is determined by setting values that indicate whether or not the initial needle-mark data is used in the calculation of offset values. The initial needle-mark data is the needle-mark data that is acquired when the first semiconductor wafer W of each lot is inspected or when the first semiconductor wafer W is inspected after the probe card 31 is replaced. The initial needle-mark data may be unstable in terms of the accuracy of contact, and using the initial needle-mark data when calculating an offset value might make it difficult to calculate a reliable offset value. Consequently, whether or not the initial needle-mark data is used to calculate an offset value is made configurable.

The data period is a setting value that indicates the period of needle-mark data that is used to calculate an offset value. To be more specific, the needle-mark data period is the number of semiconductor wafers inspected to collect the first item of needle-mark data to the last item of needle-mark data to be used to calculate an offset value. For example, assuming that 5 items of needle-mark data are needed to calculate an offset value and the data period is set to 20, the offset value is calculated if, out of the 20 semiconductor wafers inspected, 5 or more semiconductor wafers provide needle-mark data that can be used.

For example, there are times when inspecting a semiconductor wafer W gives no needle-mark data, such as when a post-contact image fails to show needle-mark ranges that are identifiable. If the period from the first item of needle-mark data to the last item of needle-mark data is long, it may be difficult to calculate an adequate offset value. Consequently, the period of needle-mark data to be used to calculate an offset value is made configurable.

The method of calculating offset values includes providing setting values that define the number of items of needle-mark data used to calculate offset values and the types of statistical values to be calculated from needle-mark data. When calculating an offset value, the number of items of needle-mark data obtained per semiconductor wafer for use in the calculation is, for example, four or five. Statistical values that can be set include, for example, the arithmetic mean, the median, the center of gravity, and the moving average.

### <<Offset Information>>

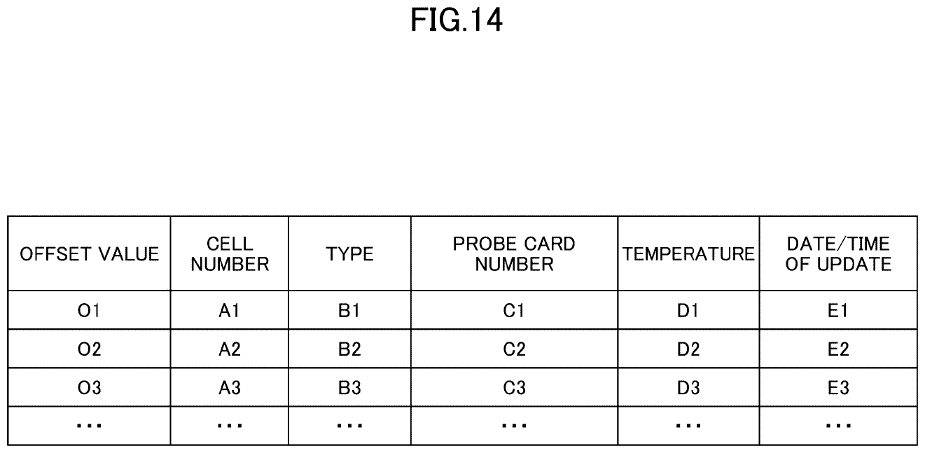

The offset information according to the present embodiment will be described with reference to FIG. 14. FIG. 14 is a conceptual diagram showing an example of offset information according to the present embodiment.

As shown in FIG. 14, the offset information according to the present embodiment refers to a body of information in which, for example, an offset value is associated with a cell number, a type, a probe card number, a temperature, and a date/time of update. Of these, the cell number, the type, the probe card number, and the temperature are environment information that represents the environment as of when the offset value was calculated.

The cell number is identification information that identifies the position of the semiconductor wafers W in an inspection system having multiple inspection devices. The type is information that indicates the type of electronic devices D. The probe card number is identification information that identifies the type of the probe card 31. The temperature is the temperature of the semiconductor wafers W or the semiconductor-wafer-mounting surface of the mounting table 10. The date/time of update is information that indicates the date and time the offset value was set.

### <Procedures>

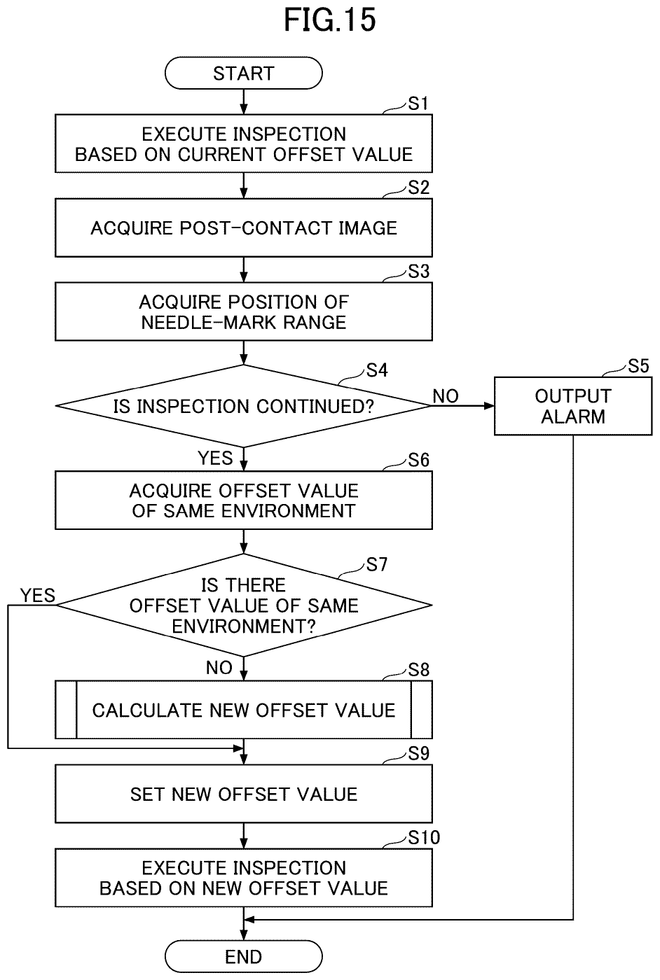

The inspection method according to the present embodiment will be described below with reference to FIG. 15. FIG. 15 is a flowchart showing an example of the inspection method according to the present embodiment. The inspection method according to the present embodiment is executed by the inspection device 1.

In step S1, first, the image-capture control unit 601 controls the image-capturing unit 40 to capture an image of pads E on a semiconductor wafer W placed on the mounting table 10. Next, based on the current offset value stored in a storage unit such as the secondary memory device 503, the inspection execution unit 607 controls the mounting table driving unit 20 to move the mounting table 10 below the inspection unit 30. This allows multiple probes 32 and multiple pads E, formed on the semiconductor wafer W placed on the mounting table 10, to face each other.

Next, the inspection execution unit 607 controls the mounting table driving unit 20 to raise the mounting table 10 with a certain amount of overdrive. This places the probes 32 in contact with respective opposing pads E. When this takes place, the tip of each probe 32 is pressed against the pads E and scrapes the surface of the pads E slightly, thus ensuring conductivity between the probes 32 and the pads E.

Next, the inspection execution unit 607 commands the tester 35 to start an inspection. The tester 35 outputs a predetermined electrical signal to the test head 33. The electrical signal output from the tester 35 is supplied to the pads E on the semiconductor wafer W via the test head 33 and the probes 32. An electrical signal is output from the pads E on the semiconductor wafer W to the tester 35 via the probes 32 and the test head 33. The tester 35 evaluates the electrical properties of the semiconductor wafer W based on the electrical signal output to the test head 33 and the electrical signal output from the test head 33 in return, and outputs the evaluation result to the control device 60.

When the inspection is completed, the inspection execution unit 607 controls the mounting table driving unit 20 to lower the mounting table 10. This makes the probes 32 move away from the pads E, and contact marks (that is, the latest needle-mark ranges) are left on the pads E by the probes 32.

In step S2, the image-capture control unit 601 controls the mounting table driving unit 20 to move the mounting table 10 below the image-capturing unit 40. This places the probes 32 in contact with respective opposing pads E.

Next, the image-capture control unit 601 controls the image-capturing unit 40 to capture an image of the semiconductor wafer W placed on the mounting table 10. By this means, a gradational, post-contact image that captures the pads E formed on the semiconductor wafer W is acquired.

Next, the image-capture control unit 601 acquires the post-contact image output from the image-capturing unit 40. The image-capture control unit 601 sends the post-contact image to the needle-mark position acquiring unit 602.

In step S3, the needle-mark position acquiring unit 602 receives the post-contact image from the image-capture control unit 601. Next, the needle-mark position acquiring unit 602 acquires, for example, the positions of the latest needle-mark ranges and the center position of the corresponding pad E from the post-contact image. The method of acquiring the positions of the latest needle-mark ranges from the post-contact image is disclosed, for example, in Unexamined Japanese Patent Application No. 2006-278381.

Next, needle-mark data representing these needle-mark ranges' positions is generated by the needle-mark position acquiring unit 602. Next, the needle-mark position acquiring unit 602 stores the needle-mark data generated thus, in the needle-mark data storage unit 611.

In step S4, the warning issuing unit 603 acquires the latest needle-mark data from the needle-mark data storage unit 611. Next, the warning issuing unit 603 reads setting information from the setting information storage unit 610. Then, the warning issuing unit 603 decides whether or not to bring the probes 32 into contact with the pad E (that is, whether or not to continue the inspection) based on the correction rules provided in the setting information.

To be more specific, based on the latest needle-mark data acquired above, the warning issuing unit 603 calculates the deviations between the positions of the latest needle-mark ranges and the center position of the pad E. Next, the warning issuing unit 603 adds the calculated deviations to the cumulative value of deviations stored in a storage unit. If the cumulative value of deviations is greater than or equal to a cumulative value threshold set forth in the correction rules, the warning issuing unit 603 decides not to bring the probes 32 into contact with the pad E (that is, decides not to continue the inspection). On the other hand, if the cumulative value of deviations is less than the cumulative value threshold set forth in the correction rules, the warning issuing unit 603 decides to bring the probes 32 into contact with the pad E (that is, decides to continue the inspection).

The warning issuing unit 603 may decide not to bring the probes 32 into contact with the pad E if the latest needle-mark data exhibits a deviation that is greater than or equal to a deviation threshold set forth in the correction rules. In this case, the warning issuing unit 603 may decide to bring the probes 32 into contact with the pad E if the deviation of the latest needle-mark data is less than the deviation threshold set forth in the correction rules.

When the warning issuing unit 603 decides not to bring the probes 32 into contact with the pad E (“NO” in step S4) (that is, decides not to continue the inspection), the process proceeds to step S5. On the other hand, when the warning issuing unit 603 decides to bring the probes 32 into contact with the pad E (“YES” in step S4) (that is, decides to continue the inspection), the process proceeds to step S6.

In step S5, the warning issuing unit 603 issues a warning to the user. The warning is issued to an output device such as a display via the input/output I/F 505 provided in the control device 60. Subsequently, the warning issuing unit 603 ends the execution of the inspection method.

In step S6, the offset acquiring unit 604 checks the current environment. The current environment is the type of the corresponding electronic device D, the identification information of the probe card 31, and the temperature of the semiconductor wafer W or the semiconductor-wafer-mounting surface of the mounting table 10. Assume that the type of the electronic device D and the identification information of the probe card 31 have been input by the user to the control device 60 and stored in the storage unit.

The temperature of the semiconductor wafer W is acquired from the infrared sensor 34. The temperature of the semiconductor-wafer-mounting surface of the mounting table 10 is acquired from the temperature sensors 11. If a semiconductor wafer W is placed on the mounting table 10, the infrared sensor 34 can acquire the temperature of the semiconductor wafer W. On the other hand, if a semiconductor wafer W is not placed on the mounting table 10, the temperature sensor 11 can acquire the temperature of the semiconductor-wafer-mounting surface of the mounting table 10.

Next, the offset acquiring unit 604 acquires offset information, including environment information that matches the current environment, from the offset information stored in the offset storage unit 612. If the current temperature matches the temperature as of when the current offset values were calculated, the offset acquiring unit 604 does not acquire offset information. If the current temperature does not match the temperature as of when the current offset values were calculated, the offset acquiring unit 604 acquires offset information including a matching electronic device D type and a matching probe card 31 ID number.

Note that whether or not a given temperature “matches” may also be determined based on whether the temperature is included in a certain range of temperatures. For example, if the current temperature is within ±10° C. of the temperature as of when the current offset values were calculated, these temperatures may be determined to “match.”

In step S7, the offset acquiring unit 604 decides whether or not offset information that matches the current environment has been acquired. If offset information that matches the current environment has not been acquired (“NO”), the offset acquiring unit 604 proceeds to step S8. Note that, even if offset information that matches the current environment has been acquired, the offset acquiring unit 604 can still proceed to step S8.

If offset information that matches the current environment has been acquired (“YES”), the offset acquiring unit 604 sends this offset information to the offset setting unit 606. In doing so, the offset acquiring unit 604 deletes the needle-mark data stored in the needle-mark data storage unit 611. Subsequently, the offset acquiring unit 604 skips step S8 and proceeds to step S9.

In step S8, the offset calculation unit 605 calculates a new offset value based on the needle-mark data stored in the needle-mark data storage unit 611 and the setting information stored in the setting information storage unit 610. The offset calculation unit 605 sends the newly calculated offset values to the offset setting unit 606.

### <<Offset Calculation Process>>

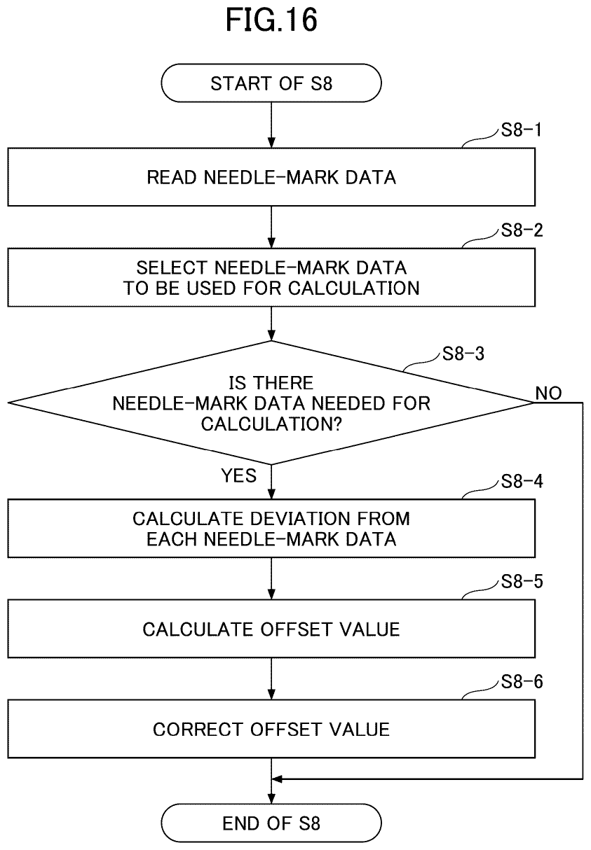

The offset calculation process (step S8 in FIG. 15) according to the present embodiment will be described in detail with reference to FIG. 16. FIG. 16 is a flowchart showing example procedures of the offset calculation process according to the present embodiment.

In step S8-1, the needle-mark data selection unit 701 reads the setting information stored in the setting information storage unit 610. Next, the needle-mark data selection unit 701 reads the needle-mark data stored in the needle-mark data storage unit 611.

In step S8-2, the needle-mark data selection unit 701 determines which items of needle-mark data, out of all the items of needle-mark data read in step S8-1, are to be used to calculate the offset value, based on the calculation rules and setting values provided in the setting information.

The needle-mark data selection unit 701 first extracts the needle-mark data included in a predetermined data period. The needle-mark data selection unit 701 then decides whether or not to use needle-mark data that indicates outliers. Whether or not outliers are used is provided in advance by a setting value. If the needle-mark data selection unit 701 decides not to use needle-mark data that indicates outliers, the needle-mark data selection unit 701 excludes, from the needle-mark data extracted, any item of needle-mark data that exhibits a deviation greater than a predetermined outlier.

Next, the needle-mark data selection unit 701 decides whether or not to use the initial needle-mark data. Whether or not the initial values are used is provided in advance by a setting value. If the needle-mark data selection unit 701 decides not to use the initial needle-mark data, the needle-mark data selection unit 701 excludes the initial needle-mark data from the extracted needle-mark data.

In step S8-3, the needle-mark data selection unit 701 decides whether or not the needle-mark data that is needed to calculate offset values was acquired in step S8-1. The needle-mark data selection unit 701 decides whether or not the needle-mark data that is needed to calculate offset values has been acquired, based on whether or not the number of items of needle-mark data required by the offset calculation method, which is determined in advance, is satisfied.

If the needle-mark data that is needed to calculate offset values has been successfully obtained (“YES” in step S8-3), the needle-mark data selection unit 701 sends the selected needle-mark data to the deviation calculation unit 702 and proceeds to step S8-4. On the other hand, if the needle-mark data that is needed to calculate offset values has not been obtained successfully (“NO” in step S8-3), the needle-mark data selection unit 701 terminates the offset calculation process.

In step S8-4, the deviation calculation unit 702 receives the needle-mark data from the needle-mark data selection unit 701. Then, for every item of needle-mark data received thus, the deviation calculation unit 702 calculates the deviation between the indicated needle-mark range's position and the center position of the corresponding pad E. The deviation calculation unit 702 then sends all the deviations calculated thus, to the offset estimation unit 703.

In step S8-5, the offset estimation unit 703 receives the deviations from the deviation calculation unit 702. The offset estimation unit 703 then estimates an offset value for each deviation, in accordance with the method of offset calculation provided in the setting information. The offset estimation unit 703 then sends the estimated offset values to the offset correction unit 704.

In step S8-6, the offset correction unit 704 receives the offset values from the offset estimation unit 703. The offset correction unit 704 then corrects the offset values by applying the correction rules provided in the setting information. The offset correction unit 704 outputs the corrected offset values as new offset values.

For example, on an XY plane, the offset correction unit 704 first identifies a range in which an original position is located and a range in which a new position is located. Next, the offset correction unit 704 selects a predetermined correction rule based on the combination of the original position's range and the new position's range. The offset correction unit 704 then corrects the corresponding estimated offset value according to the selected correction rule. Note that, depending on the correction rule that is selected, the corresponding estimated offset value may be used as is, or the corresponding estimated offset value may be discarded and an alarm may be issued.

The subsequent procedures will be described referring back to FIG. 15. In step S9, the offset setting unit 606 receives the new offset values from the offset calculation unit 605 or the offset acquiring unit 604. The offset setting unit 606 sets the received new offset values as current offset values. To be more specific, the offset setting unit 606 replaces the current offset values stored in the storage unit, with the new offset values. Therefore, in the following processes, the new offset values received from the offset calculation unit 605 or the offset acquiring unit 604 will be used as “current” offset values.

In step S10, the inspection execution unit 607 controls the mounting table driving unit 20 and the tester 35 based on the current offset values stored in the storage unit (that is, the new offset values set in step S9) to perform an electrical inspection of the semiconductor wafer W placed on the mounting table 10. The inspection step is the same as step S1 and will not be described here.

### Advantages of Embodiment

The inspection device 1 of the present embodiment sets new offset values based on needle-mark ranges that have been formed by probes 32 having contacted pads E, and brings the probes 32 into contact with the pads E based on the new offset values. In other words, the inspection device 1 of the present embodiment automatically adjusts offset values based on needle-mark ranges that the probes 32 have formed upon contact with pads E. Therefore, according to the inspection device 1 of the present embodiment, the probes 32 can be brought into accurate contact with the pads E formed on semiconductor wafers W.

Given an offset value that is set, the inspection device 1 of the present embodiment associates this offset value with the environment information applied when the offset value was calculated, and, if an offset value that is calculated based on the same environment information is found, uses this offset value. Thus, the inspection device 1 of the present embodiment can bring the probes 32 into accurate contact with the pads E formed on semiconductor wafers W, and continue using offset values that have been used earlier.

Depending on how much a needle-mark range's position deviates with respect to the center position of a corresponding pad E, the inspection device 1 of the present embodiment calculates the offset value based on different rules. The rules for calculating offset values are stored as setting information and can be edited as appropriate. Accordingly, with the inspection device 1 of the present embodiment, appropriate rules can be applied depending on the tendency of deviation in contact positions, and the probes 32 can be brought into accurate contact with the pads E formed on electronic devices D.

The inspection device 1 of the present embodiment decides whether or not to bring the probes 32 into contact with the pads E based on the deviations between the positions of needle-mark ranges and the center position of a corresponding pad E. If a given probe 32 exhibits a deviation that is greater than a predetermined threshold, the inspection device 1 of the present embodiment does not bring the probe 32 into contact with the pad E, and outputs an alarm instead. Accordingly, the inspection device 1 of the present embodiment can prevent troubles from occurring.

### NOTES

According to the embodiment described above, the current offset values are an example of a first offset value. The new offset values are an example of a second offset value. The inspection device and inspection method according to the embodiment disclosed herein are illustrative in all respects, and are not limiting in any way. The embodiment may be modified and improved in a variety of ways without departing from the scope and spirit of the accompanying claims. The matters described in the above embodiment may be structured or designed differently, or used in various combinations, insofar as an inconsistency does not arise.

What is claimed is:

1. An inspection method executed by an inspection device including:
a mounting table on which an object of inspection is to be placed; and
a probe card having a probe for use in inspecting the object,
the inspection method comprising:
bringing the probe into contact with an electrode, formed in the object, based on a first offset value;
setting a second offset value based on a needle mark that is formed when the probe is brought into contact with the electrode based on the first offset value; and
bringing the probe into contact with the electrode based on the second offset value.

2. The inspection method according to claim 1, further comprising storing the second offset value in association with at least one of:
a type of the object;
a type of the probe card; or
a temperature of the object or the mounting table.

3. The inspection method according to claim 2, further comprising acquiring the second offset value based on:
the type of the object;
the type of the probe card; or
the temperature of the object or the mounting table.

4. The inspection method according to claim 3, wherein the second offset value is calculated based on different rules depending on a deviation between a position of the needle mark and a center position of the electrode.

5. The inspection method according to claim 4, wherein the different rules include rules among which a target position where the probe is brought into contact with the electrode varies.

6. The inspection method according to claim 5, wherein the target position is determined based on a positional relationship between a position of a needle mark used to calculate the first offset value and a position of the needle mark formed when the probe is brought into contact with the electrode based on the first offset value.

7. The inspection method according to claim 1, further comprising determining whether or not to bring the probe into contact with the electrode based on a deviation between a center position of the electrode and a position of the needle mark that is formed when the probe is brought into contact with the electrode based on the first offset value.

8. The inspection method according to claim 7, wherein whether or not to bring the probe into contact with the electrode is determined by comparing a cumulative value of deviations between positions of needle marks and the center position of the electrode against a predetermined threshold.

9. The inspection method according to claim 8, further comprising issuing a warning upon a determination that the probe is not to be brought into contact with the electrode.

10. An inspection device comprising:
a mounting table on which an object of inspection is to be placed;
a probe card having a probe for use in inspecting the object; and
a control device configured to perform an inspection method including:
bringing the probe into contact with an electrode, formed in the object, based on a first offset value;
setting a second offset value based on a needle mark that is formed when the probe is brought into contact with the electrode based on the first offset value; and
bringing the probe into contact with the electrode based on the second offset value.

11. A non-transitory computer readable recording medium storing a program that, when executed by a control device, causes the control device to perform an inspection method, the control device including:
a mounting table on which an object of inspection is to be placed; and
a probe card having a probe for use in inspecting the object, and
the inspection method including:
bringing the probe into contact with an electrode, formed in the object, based on a first offset value;
setting a second offset value based on a needle mark that is formed when the probe is brought into contact with the electrode based on the first offset value; and
bringing the probe into contact with the electrode based on the second offset value.
